(19) United States
(12) Patent Application Publication
(10) Pub. No.: US 2008/0050523 A1
(43) Pub. Date: Feb. 28, 2008

(54) Unit-Layer Post-Processing Catalyst Chemical-Vapor-Deposition Apparatus and Its Film Forming Method

(76) Inventors: Makiko Kitazoe, Chiba (JP); Hiromi Itho, Chiba (JP); Shin Asari, Chiba (JP); Kazuya Saito, Chiba (JP)

Correspondence Address: ARENT FOX LLP, 1050 CONNECTICUT AVENUE, N.W., SUITE 400, WASHINGTON, DC, 20036, US

(21) Appl. No.: 10/593,444

(22) PCT Filed: Mar. 25, 2005
(86) PCT No.: PCT/JP05/05566

§ 371 Date: Feb. 5, 2007

(30) Foreign Application Priority Data
Mar. 26, 2004 (JP) 2004-091987

(51) Int. Cl. C23C 16/00; C23C 14/00

(52) U.S. Cl. 427/255.26; 118/715

(57) ABSTRACT

To provide a unit-layer post-treatment catalyst vapor-deposition apparatus and unit-layer post-treatment film forming method capable of improving in-face uniformity, step coverage, and film quality of a silicon nitride film or the like and forming a thin film by performing surface treatment after forming a film for each unit layer.

A thin film post-treated for each unit layer is laminated by using a film forming step of introducing mixed gas of silane gas and ammonia gas into a reactive vessel 2 as a source gas like a rectangular pulse and contacting with and thermal-decomposing the source gas by a catalyst body 8, and forming a silicon nitride film on a substrate 5, one surface treating step of bringing ammonia gas into contact with the catalyst body 8 and then bleaching the ammonia gas on the surface of a silicon nitride film on the substrate 5 and other surface treating step of bleaching hydrogen gas on the surface of the silicon nitride film on the substrate 5 after bringing hydrogen gas into contact with the catalyst body 8 as one cycle and repeating the step of one cycle.

### TECHNICAL FIELD

The present invention relates to a unit-layer post-processing catalyst chemical-vapor-deposition apparatus according to a catalyst chemical vapor deposition method for forming a film every unit layer and then surface-treating and laminating the thin films and its film forming method.

### BACKGROUND ART

Various types of semiconductor devices, a liquid-crystal display (LCD) and the like are respectively fabricated by forming a predetermined thin film on a substrate. As the film forming method, a CVD method (also referred to as chemical vapor growth method or chemical vapor deposition method) has been used so far, for example.

As the CVD method, heat CVD method, plasma CVD method and the like have been known so far. Recently, however, a catalyst CVD method (also referred to as Cat-CVD method or hot-wire CVD method) has been practically used which forms a deposited film on a substrate by using an element wire made of heated tungsten or the like (hereafter referred to as catalytic body) as a catalyst, thereby bringing a source gas supplied into a reaction chamber into contact with the catalytic body and decomposing the gas.

The catalyst CVD method can forma film at a low temperature compared to the case of the heat CVD method and it does not have a problem that a substrate is damaged due to the generation of plasma like the case of a plasma CVD method. Therefore, the catalyst CVD method is noted as a film forming method for a next-generation semiconductor device, display device (such as LCD) and the like.

When forming a silicon nitride film in accordance with the above catalyst CVD method, a silicon nitride film having a necessary thickness is conventionally formed on a substrate through one-time film forming step by introducing a mixed gas containing silane gas (SiH₄) and ammonium gas (NH₃) into a reactive vessel as a source gas, heating a catalyst body such as a tungsten filament, and bringing the introduced source gas into contact with the catalyst body and decomposing the gas (refer to, for example, Patent Document 1).

Patent Document 1: Japanese Patent Laid-Open No. 2002-367991

However, a silicon-nitride film formed by the conventional CVD method like one disclosed in the above Patent Document 1 does not have a good in-face uniformity of a film thickness and is insufficient in step coverage and a film having a good current-voltage (I-V) withstand-voltage characteristic is not obtained. Therefore, the film must be improved.

Therefore, in view of the above problem, it is an object of the present invention to provide a unit-layer post-processing catalyst vapor-deposition apparatus capable of improving the in-face uniformity of a silicon nitride film, step coverage, and film quality such as a I-V withstand voltage characteristic and forming a film every unit layer, thereafter surface-treating and laminating thin films and its film forming method.

### DISCLOSURE OF THE INVENTION

To achieve the above object, the invention of claim 1 among unit-layer post-processing catalyst chemical-vapor-deposition apparatuses of the present invention is a catalyst chemical-vapor- deposition apparatus for forming a thin film on a substrate by using the catalyst action of an exothermic catalytic body resistance-heated in a reactive vessel capable of performing vacuum pumping, which is provided with a gas supply system capable of introducing flow rates of thin-film-component-contained gas and hydrogen gas into the reactive vessel like a pulse and an exhaust system capable of realizing vacuum pumping and pressure control and has a constitution in which the thin-film-component-contained gas and hydrogen gas introduced like a pulse contact with the exothermic catalyst body and decompose, a thin film for each unit layer is formed on the substrate and the thin film for each unit layer is surface-treated to form a laminated thin film.

Moreover, the invention of claim 2 is characterized in that the surface treatment is one or both of surface treatment by a thin-film-component-contained gas excluding silicon and including active species and surface treatment by hydrogen gas containing active species.

Furthermore, the invention of claim 3 is characterized in that the hydrogen gas is applied to the exothermic catalytic body to reproduce a catalytic performance.

The invention of claim 4 is characterized in that the surface treatment is one or both of extraction treatment of surplus thin-film component and direct addition treatment of thin-film component.

The invention of claim 5 is characterized by using nitrogen gas or rare gas instead of the hydrogen gas.

The invention of claim 6 is characterized in that the thin-film-component-contained gas is any one of hydride of silicon and halide of silicon, any one of nitrogen and hydride of nitrogen, or both of nitrogen and hydride of nitrogen.

The invention of claim 7 is characterized in that the thin-film-component-contained gas including active species in the surface treatment is any one of nitrogen and hydride of nitrogen or both of them.

The invention of claim 8 among unit-layer post-processing film forming methods of the present invention is a catalyst chemical vapor deposition method for using the catalyst action of an exothermic catalytic body resistance-heated in a reactive vessel capable of performing vacuum pumping and thereby forming a thin film on a substrate, in which the following steps are included: an activating step of introducing flow rates of thin-film-component-contained gas and hydrogen gas like a pulse, bringing the gases into contact with an exothermic catalytic body and thereby, generating active species, a film forming step of forming a thin film every unit layer on a substrate, a film forming step of surface-treating a thin film for each unit layer on the substrate, a surface treating step of performing surface treatment of a thin film for unit layer by hydrogen gas containing active species, another surface treating step of surface-treating a thin film every unit layer by thin-film-component-contained gas including active species to form a thin film laminated by using a series of steps for respectively forming a unit-layer thin film as one cycle.

Moreover, the invention of claim 9 is characterized by repeating any one of the one surface treating step and the other surface treating step up to a plurality of times in one cycle in addition to the above configuration.

Furthermore, the invention of claim 10 is characterized in that one or both of the one surface treating step and the other surface treating step and the film forming step of forming a thin film for each unit layer on a substrate are continuously performed.

The invention of claim 11 is characterized by vacuum-pumping remaining gas after any one of the one surface treating step and the other surface treating step.

The invention of claim 12 is characterized in that the one surface treating step is a step of extracting surplus thin-film component and the other surface treating step is a step of adding a thin-film component.

The invention of claim 13 is characterized in that a final step of one cycle is a step of performing surface treatment by a thin-film-component-contained gas excluding silicone including active species.

The invention of claim 14 is characterized by using any one of nitrogen gas and rare gas instead of the hydrogen gas.

The invention of claim 15 is characterized in that the thin-film-component-contained gas includes any one of hydride of silicon and halide of silicon and any one of nitrogen and hydride of nitrogen or both of them.

The invention of claim 16 is characterized in that the thin-film-component-contained gas including active species in the surface treatment contains one or both of nitrogen gas and hydride of nitrogen.

The invention of claim 17 is characterized in that thin-film-component-contained gas contains monosilane gas and ammonia gas, the film forming step forms a silicon nitride film on a substrate every unit layer and the other surface treating step surface-treats a silicon nitride film every unit layer by ammonium gas including active species.

The invention of claim 18 is characterized in that the final step of one cycle is a step of performing surface treatment by ammonium gas which is thin-film-component-contained gas including active species.

Since a unit-layer post-processing catalyst vapor-deposition apparatus of the present invention can change gas introduction at once, it has advantages that it is possible to form a film for each unit layer, perform surface treatment for each formed unit layer, and improve in-face film-thickness uniformity, step coverage, and film quality.

Moreover, a unit-layer post-processing film forming method of the present invention has an advantage that it is possible to form a laminated thin film in which the in-face uniformity of a film thickness, step coverage, and film quality are improved because surface treatment is performed after film formation for each unit layer.

### BRIEF DESCRIPTION OF THE DRAWINGS

FIG. 1 is a schematic block diagram showing a unit-layer post-processing catalyst chemical-vapor-deposition apparatus of an embodiment of the present invention;

FIG. 2 is an illustration showing an example of a gas-supply timing chart of a unit-layer post-processing film forming method of the present embodiment;

FIG. 3 is an illustration showing a gas supply timing chart;

FIG. 4 is an illustration showing a gas supply timing chart;

FIG. 5 is an illustration showing a gas supply timing chart;

FIG. 6 is an illustration showing a gas supply timing chart;

FIG. 7 is an illustration showing a gas supply timing chart;

FIG. 8 is an illustration showing a step coverage change when changing only NH₃ supply;

FIG. 9 is an illustration when comparing effects of H₂ and N₂ as step-coverage improvement additional gases under NH₃ supply suppression;

FIG. 10 is an illustration showing in-situ post-processing pressure dependency;

FIG. 11 is an illustration showing a hydrogen treatment effect at the time of composite post processing;

FIG. 12 is an illustration showing gas atmosphere dependency at the time of composite post processing;

FIG. 13 is an illustration showing the unit film thickness dependency of a laminated Cat-SiN film;

FIGS. 14(a) and 14(b) are illustrations showing composition ratios between SiN films on silicon substrates by ammonium-suppressed SiN₄/NH₃/H₂, in which FIG. 14 (a) shows a case of making hydrogen-gas surface treatment precede and FIG. 15(b) shows a case of making ammonia-gas surface treatment precede;

FIGS. 15(a) and 15(b) are illustrations showing composition ratios between SiNs formed on 50 Å SiN films on silicon substrates, in which FIG. 15 (a) shows a case of making hydrogen-gas surface treatment precede and FIG. 15 (b) shows a case of making ammonium-gas surface treatment precede;

FIG. 16 is an illustration showing gas-introduction sequence dependency at the time of post processing;

FIG. 17 is an illustration showing hydrogen contents of a unit-layer film by standard Cat-SiN, laminated film by adaptive Cat-SiN unit-layer post processing, and unit-layer film by PECVD-SiN;

FIG. 18 is an illustration for comparing hydrogen contents of Cat-SiN films;

FIG. 19 is an illustration showing film forming conditions of the film forming method of Example 1 and a conventional film forming method;

FIG. 20 is an illustration showing film forming conditions of the film forming method of the Example 2 and a conventional film forming method;

FIG. 21 is an illustration showing results of measuring coverage and I-V electricity withstand voltage characteristic for silicon nitride films formed by the film forming method of Example 2 and a conventional film forming method;

FIG. 22 is an illustration showing film forming conditions of the film forming method of Example 3 and a conventional film forming method; and

FIG. 23 is an illustration showing results of measuring in-face uniformity of a film thickness and corrosion resistance (etching rate) for an etching solution for silicon nitride films formed by the film forming method of Example 3 and a conventional film forming method.

### DESCRIPTION OF SYMBOLS

1: Unit-layer post-processing catalyst chemical-vapor-deposition apparatus
2: Reactive vessel
3. Source gas
4: Gas introducing portion
5: Substrate
6: Substrate holder
8: Catalyst body
9: Gas-supply manifold
10: Reactive system
11: Gas supply system
13: Exhaust system
15: Gas exhaust nozzle
21: Silane-gas introducing line
23: Ammonium-gas introducing line
25: Hydrogen-gas introducing line
27: Nitrogen-gas introducing line
31, 53: Manual valve
33: Mass-flow controller
34: First pneumatic operation valve
35: Second pneumatic operation valve
37: Check valve
39: Vent line
41: Auxiliary pump
43: Turbo molecular pump
45: Pressure-control main valve
47: Subvalve
49: Vacuum gauge
51: Relief valve
55: Gate valve
57: Load lock chamber

### BEST MODE FOR CARRYING OUT THE INVENTION

A unit-layer post-processing catalyst chemical-vapor-deposition apparatus of the present invention is a catalyst chemical-vapor-deposition apparatus for using the catalyst action of an exothermic catalyst body resistance-heated in a reactive vessel capable of performing vacuum pumping and thereby forming a thin film on a substrate, which is provided with a gas supply system capable of introducing flow rates of thin-film-component-contained gas and hydrogen gas into the reactive vessel like a pulse and an exhaust system capable of performing vacuum pumping and pressure control and forms a laminated thin film by bringing the thin-film component-contained gas and hydrogen gas introduced like a pulse into contact with the exothermic catalyst body, decomposing them, forming a thin film for each unit layer on the substrate, and surface-treating the thin film for each unit layer.

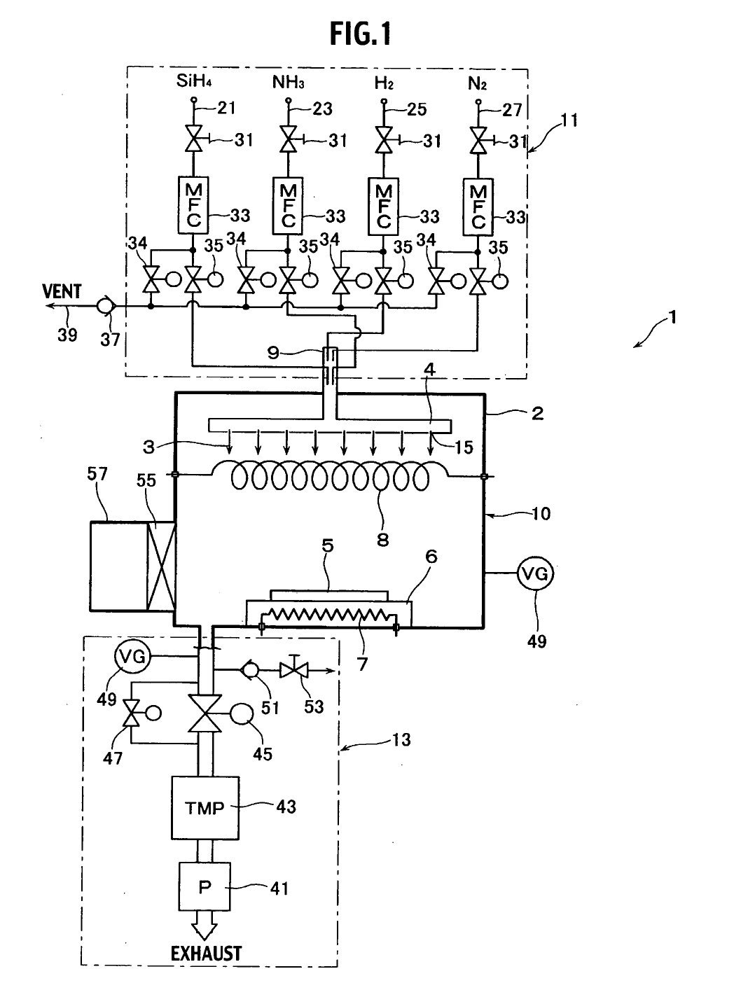

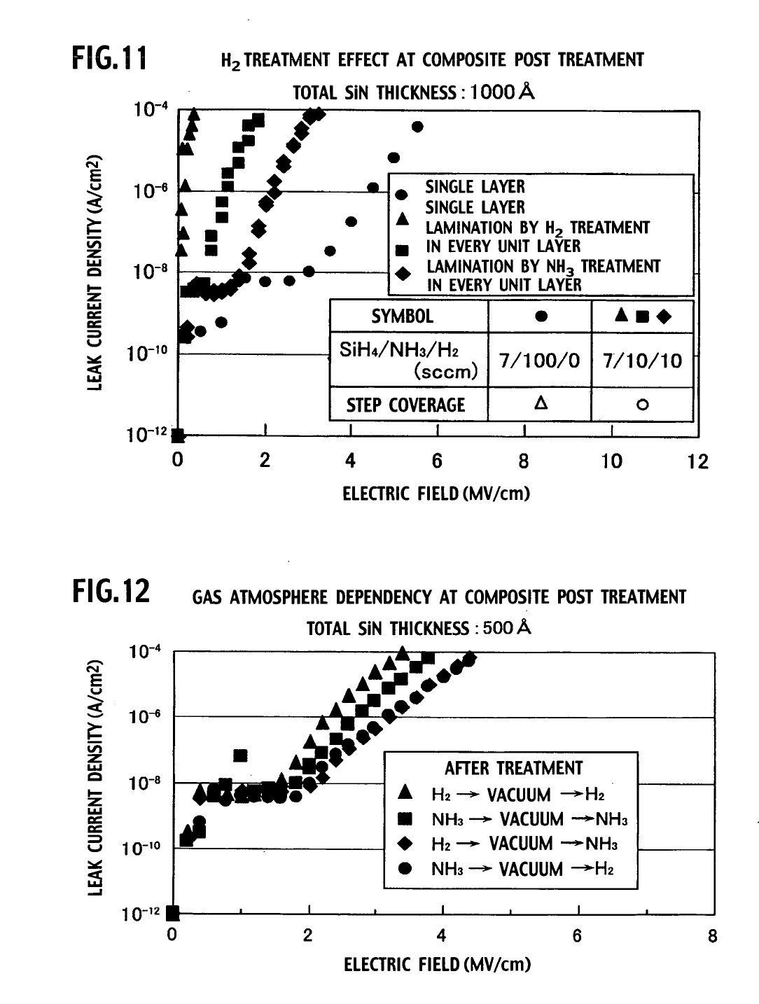

Hereafter, an embodiment to be preferably used for a unit-layer post-processing catalyst vapor-deposition apparatus of the present invention is described by using the same symbols for substantially-same or corresponding components in accordance with FIGS. 1 to 18.

FIG. 1 is a schematic block diagram showing a unit-layer post-processing catalyst chemical-vapor-deposition apparatus of the present invention.

The unit-layer post-processing catalyst chemical-vapor-deposition apparatus 1 of this embodiment is provided with a reactive system 10, gas supply system 11, and exhaust system 13.

A gas introducing portion 4 for introducing a source gas 3 into a reactive vessel 2 of the reactive system 10 of the unit-layer post-processing catalyst chemical-vapor-deposition apparatus 1 is provided at the upper portion in the reactive vessel 2 of the reactive system 10 and a substrate holder 6 for mounting a substrate 5 on the position facing the gas introducing portion 4 is provided at the lower portion in the reactive vessel 2.

A heater 7 for heating the substrate 5 to be mounted on the substrate holder 6 up to a predetermined temperature is provided in the substrate holder 6.

Moreover, a catalyst body 8 having a catalyst action for heating and decomposing a source gas introduced from the gas introducing portion 4 is provided at the gas introducing-portion-4 side between the gas introducing portion 4 and substrate holder 6 in the reactive vessel 2.

A gas exhaust nozzle 15 is provided at the catalyst-body-8 side of the gas introducing portion 4 so that the exhausted source gas 3 immediately contacts with the catalyst body 8.

In the case of this embodiment, the catalyst body 8 uses a high-melting-point metallic thin line such as a tungsten thin line wound like a coil. However, it is not limited to this, and as other material, it is possible to use iridium, rhenium, indium, molybdenum, tantalum, niobium, and the like. Moreover, an alloy of the above substances may be used.

The gas supply system 11 for supplying respectively silane gas (SiH₄), ammonium gas (NH₃), and hydrogen gas (H₂) serving as a source gas is connected to a gas-supply manifold 9 connected to the gas introducing portion 4 and silane gas and ammonium gas are mixed and supplied to the gas introducing potion 4 through the gas-supply manifold 9.

As thin-film-component-contained gas including silicon serving as a thin-film component, it is possible to use not only silane gas but also hydride of Si such as disilane (Si₂H₆), trisilane (Si₂H₈), silicon tetrafluoride (SiF₄), silicon tetrachloride (SiCl₄), and dichlorosilane (SiH₂Cl₂) or halogen-element-contained Si source gas.

Moreover, as gas containing a nitrogen component, it is possible to use nitrogen hydride containing nitrogen such as nitrogen (N₂) or hydrazine (N₂H₄) in addition to ammonia.

It is possible to use rare gas and nitrogen gas such as argon and helium in addition to hydrogen gas.

In this case, thin-film-component-contained gas includes steam. For example, gas which is liquid at room temperature is used as thin-film-component-contained gas in which steam pressure is adjusted through bubbling by carrier gas.

The gas supply system 11 has, for supplying a source gas 3, a silane-gas introducing line 21, an ammonia-gas introducing line 23, a hydrogen-gas introducing line 25, and a nitrogen-gas introducing line 27 and each line can set, control, and instantaneously change the mass flow rate of the source gas by a manual valve 31, a mass-flow controller 33, a first pneumatic operation valve 34, and a second pneumatic operation valve 35 and the source gas is supplied to the gas supply manifold 9.

The first pneumatic operation valve 34 and second pneumatic operation valve 35 minimize the fluctuation of a set flow rate and changes the rectangular-pulsed mass flow rate to the reactive-vessel side.

When supplying the rectangular-pulsed mass flow rate to the reactive-vessel side, it is possible to realize a rectangular-step-pulsed mass flow rate by opening the first pneumatic operation valve 34 and closing the second pneumatic operation valve 35 before introducing gas, supplying a predetermined set flow rate to the vent side to realize a stable mass flow rate, and then instantaneously changing opening and closing of the first pneumatic operation valve 34 and second pneumatic operation valve 35.

When a source gas is supplied to the vent-side line, nitrogen gas is supplied correspondingly to the supply of the source gas. In FIG. 1, reference numeral 37 of a vent line 39 denotes a check valve.

The nitrogen-gas introducing line 27 supplies nitrogen gas to be used for purge of the reactive system 10 and normal-pressure return after a film is formed.

The exhaust system 13 is provided with an auxiliary exhaust pump 41, a turbo molecular pump 43, a pressure-control main valve 45, a subvalve 47, and a vacuum gauge 49 and the reactive vessel 2 can realize vacuum pumping.

Reference numeral 51 denotes a relief valve, 53 denotes a manual valve, and this line denotes a vent line for return to normal pressure.

The pressure-control main valve 45 controls the opening degree of a valve so as to realize a set pressure in accordance with a detection signal of the vacuum gauge 49 and controls a vacuum degree in the reactive vessel 2.

The reactive system 10, gas supply system 11, and exhaust system 13 can set opening/closing of a valve due to vacuum-pumping or introduction of gas and mass flow rate and a process sequence such as current supply to a catalyst body is controlled by a not-illustrated computer so that recipes of process condition and sequence processing can be set from an operation panel.

In FIG. 1, reference numeral 55 denotes a gate valve and 52 denotes a load lock chamber.

Then, a method for using the unit-layer post-processing catalyst chemical-vapor-deposition apparatus 1 is described below.

First, a substrate is conveyed to the load lock chamber 57 and then, the substrate 5 is brought into the reactive vessel 2 through the gate valve 55 and mounted on the substrate holder 6.

Then, the reactive vessel 2 is purged by hydrogen gas and nitrogen gas while being vacuum-pumped, and then is controlled to a predetermined pressure by these purge gases.

In this case, the heater 7 is electrified and resistance-heated to heat the substrate 5 on the substrate holder 6 to a predetermined temperature (for example, about 200 to 600° C.) and the catalyst body (such as tungsten thin line) 8 is electrified and resistance-heated to heat the catalyst body 8 to a predetermined temperature (for example, about 1,600 to 1,800° C.).

Moreover, a stable mass flow rate is realized by opening the first pneumatic operation valve 34 and closing the second pneumatic operation valve 35 before introducing thin-film-component-contained gas and supplying a predetermined set flow rate to the vent side.

Then, a source gas (mixed gas of silane gas and ammonium gas) is emitted to the catalyst body 8 from a plurality of gas exhaust nozzles 15 formed on the lower face of the gas introducing portion 4 by instantaneously changing opening and closing of the first pneumatic operation valve 34 and the second pneumatic operation valve 35 and introducing the mass flow rate of the source gas to the gas introducing portion 4 through the gas supply pipe 9 like a rectangular pulse.

Thereby, the source gas is contact-heat-decomposed by the heated catalyst body 8 and a silicon nitride film is formed on the substrate 5 by using every single molecular layer as a unit layer (this step is hereafter referred to as film forming step).

In the case of the film forming conditions in this case, the flow rate of silane gas (SiH₄) is 7 sccm, that of ammonium gas (NH₃) is 10 sccm, that of hydrogen gas (H₂) is 10 sccm, pressure in the reactive vessel 2 is 10 Pa, and temperature of the catalyst body 8 is 1,700° C. In the case of this embodiment, a silicon nitride film having a very small thickness of 1 nm is obtained through one-time film forming step for, for example, 10 sec.

Then, hydrogen gas is introduced into the gas introducing portion 4 for, for example, 15 sec through the gas-supply manifold 9 after the one-time unit-layer film forming step, hydrogen gas emitted from the gas exhaust nozzle 15 is activated after the gas passes through the heated catalyst body 8 and supplied onto the substrate 5.

Thereby, the surface of the silicon nitride film formed on the substrate 5 is bleached by the activated hydrogen gas and the composition of the surface of the silicon nitride film is improved (hereafter, this step is referred to as one surface treating step).

Then, ammonium gas is continuously introduced into the gas introducing portion 4 through the gas-supply manifold 9 after the one surface treating step and the ammonium gas emitted from the gas exhaust nozzle 15 is activated when passing through the heated catalyst body 8 and supplied onto the substrate 5.

By repeating a series of the cycles, a laminated thin film whose surfaces is treated every unit layer is deposited.

Thus, this embodiment can realize instantaneous change of gas introduction, pressure control, and high-speed vacuum pumping. Therefore, it is possible to introduce thin-film-component-contained gas and hydrogen gas like a rectangular pulse and for example, the gases contact with an exothermic catalyst body at 1,700° C. and decompose and form a thin film every unit layer on a substrate. The thin film for each unit layer is surface-treated to form a laminated thin film.

Then, a unit-layer post-processing film forming method for each unit layer using the unit-layer post-processing catalyst chemical-vapor-deposition apparatus 1 is described.

This unit-layer post-processing film forming method is a catalyst chemical-vapor-deposition method for forming a thin film on a substrate by using the catalyst action of an exothermic catalyst body resistance-heated in a reactive vessel capable of performing vacuum pumping, which includes an activating step of introducing flow rates of thin-film-component-contained gas and hydrogen gas like a pulse, bringing the gases into contact with the exothermic catalyst body, and generating active species, film forming step of forming a thin film for each unit layer on the substrate, a film forming step of surface-treating a thin film for each unit layer on the substrate, a surface treating step of performing surface treatment of a thin film for unit layer by hydrogen gas containing active species, and a step of performing surface treatment independently of before and after other surface treating step of surface-treating a thin film every unit layer by thin-film-component-contained gas including active species to form a thin film laminated by using a series of steps for respectively forming a unit-layer thin film as one cycle.

The above mentioned is described below in detail.

As process conditions, the temperature of W (tungsten) serving as a catalyst (Cat) line is set to 1,700° C., the temperature of a substrate-heating heater is set to 100 to 300° C., and 8-inch Si wafer is used as a substrate.

For example, a silicon nitride film is described below.

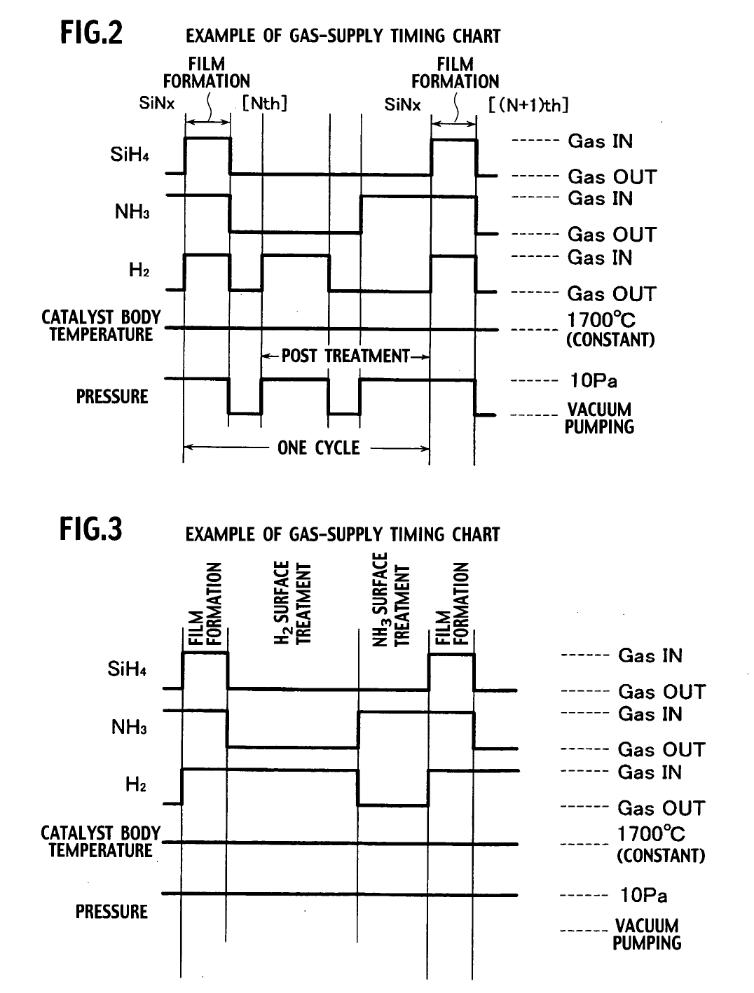

FIG. 2 is an illustration showing an example of a gas-supply timing chart of the unit-layer post-processing film forming method of this embodiment.

In FIG. 2, the unit-layer post-processing film forming method of this embodiment forms a unit layer SiN under conditions of SiH₄/NH₃/H₂=[7/10/10]sccm and 10 Pa and then performs exhausting for 5 sec to perform in-situ post processing by H₂.

It is assumes as one cycle to thereafter perform exhausting for 5 sec again and moreover perform in-situ post processing by NH₃.

In this timing chart, after post processing by NH₃ which is the component gas of a silicon nitride film, film formation is continuously and sequentially performed. Therefore, post processing and film formation are performed as one processing.

FIGS. 3 to 7 show other examples of gas-supply timing charts. In the case of each common process conditions, the temperature of an exothermic catalyst body is 1,700° C. and pressure is 10 Pa.

FIG. 3 is an illustration showing film formation→hydrogen surface treatment→ammonia surface treatment→film formation, . . .

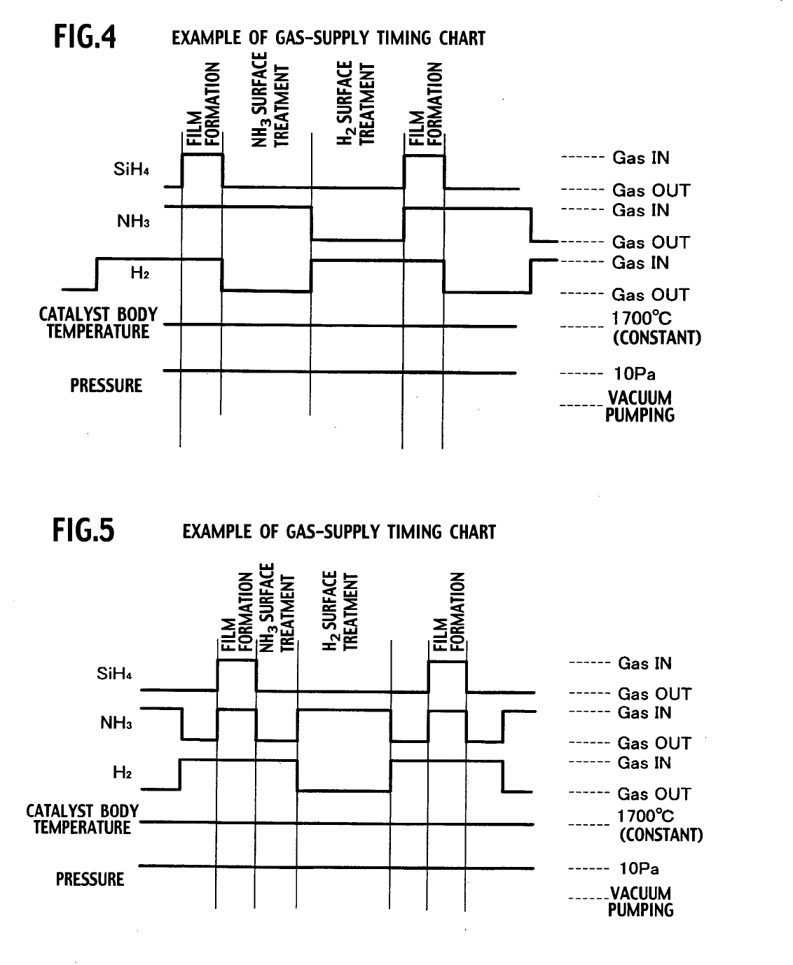

FIG. 4 is an illustration showing film formation→ammonia surface treatment→hydrogen surface treatment→film formation→ . . . ,

FIG. 5 is an illustration showing film formation→hydrogen surface treatment→ammonia surface treatment→hydrogen surface treatment→film formation→ . . . ,

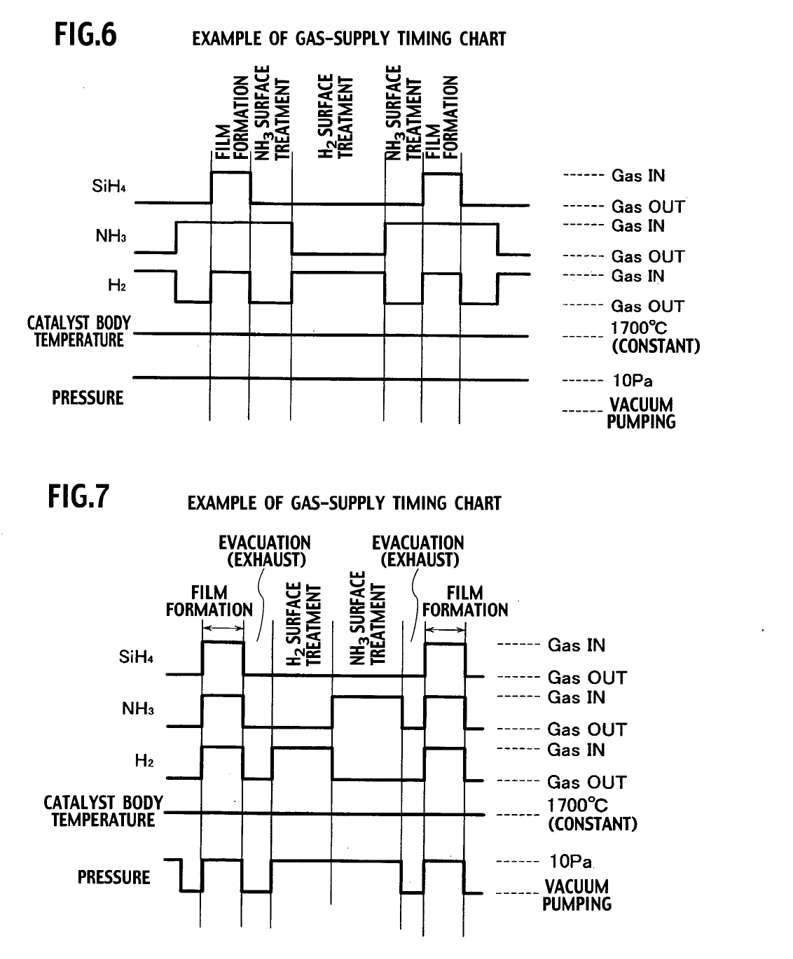

FIG. 6 is an illustration showing film formation→ammonia surface treatment→hydrogen surface treatment→ammonia surface treatment→film formation→ . . . , and

FIG. 7 is an illustration showing film formation→vacuum-pumping→hydrogen surface treatment→ammonia surface treatment→vacuum-pumping→film formation→ . . .

In the case of the example shown in FIG. 3, hydrogen gas introduction in film formation and subsequent hydrogen surface treatment are continuously performed and moreover, after ammonia surface treatment, ammonia gas introduction in film formation is continuously performed.

When performing introduction of source gas in film formation and surface treatment as one processing, it is possible to minimize fluctuations of flow rate and pressure.

In the case of the example shown in FIG. 7, the gas memory effect is vanished by performing vacuum-pumping before and after film formation and clearing away atmospheric remaining gas.

Thus, by performing vacuum-pumping before and after film formation, it is possible to secure presence or absence of gas supply and perform, for example, film formation for each single molecular layer.

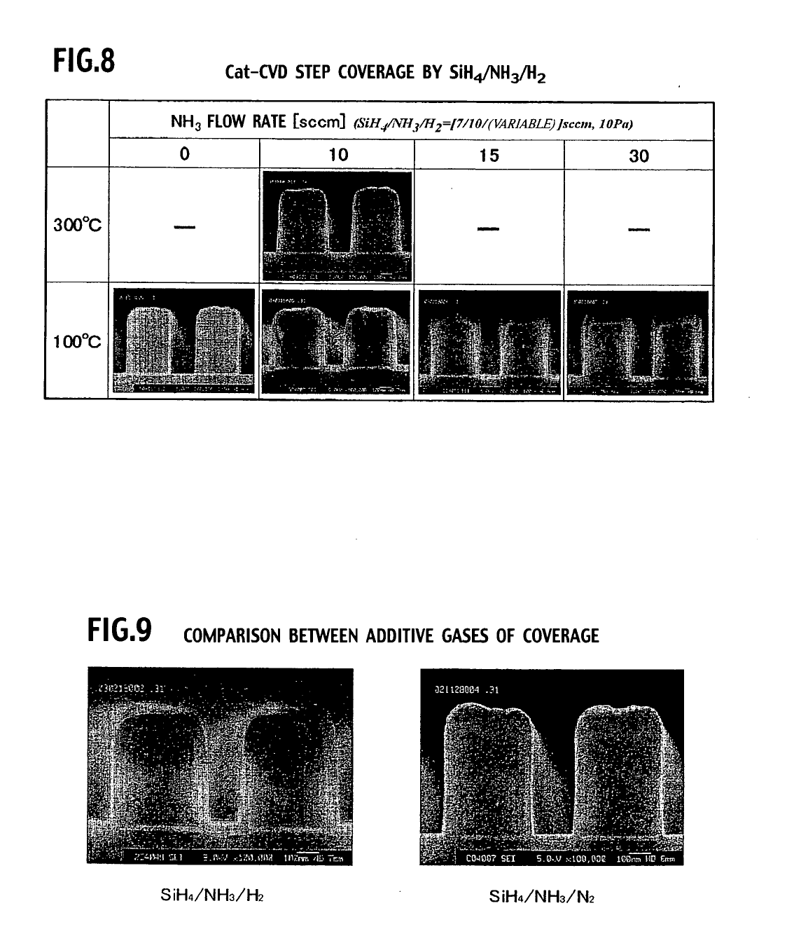

FIG. 8 shows step coverage change when changing only NH₃ supply while a process condition keeps supply of SiH₄/H₂ constant ([7/10] sccm).

As shown in FIG. 8, improvement of step coverage is not progressive for restraint of NH₃ supply. When step coverage improvement is extremely restrained by exceeding a certain limit ([SiH₄/NH₃] supply ratio=up to approx. ½), the improvement is destructively and suddenly performed. However, in the case of a film forming system by only [SiH₄/H₂] material which completely cuts-off supply of NH₃ (that is, a-Si film forming system by Cat-CVD), step coverage is deteriorated again.

Moreover, when raising substrate temperature setting, step coverage improvement tends to disappear.

FIG. 9 is an illustration of comparing effects of H₂ and N₂ serving as step-coverage improving additive gases while supply of NH₃ is restrained.

As shown in FIG. 9, step coverage is very good in hydrogen gas compared to the case of nitrogen gas as additive gas.

Therefore, H₂ is preferable as the kind of additive gas for improvement of step coverage.

From FIGS. 8 and 9, it seems that it is shown that surface process inhibition currently deposited which is estimated by the fact that the surface process inhibition is present in the competitive adsorption process of the Cat radical derived from HN₃ (Cat-NH₃) and Cat radical or H atom (Cat-H₂) derived from H₂ occurs only on the SiN surface which is extremely Si rich.

One of functions of additive H₂ in the SiN-film Cat-CVD system can point out the possibility of back etch species under [SiH₄/ NH₃] supply condition in which an Si-rich SiN film is formed.

It is considered that surplus Si produced on the surface of the Si-rich SiN film being deposited immediately provides the attack site of an etching reaction for producing SiHn (n≦4) vapor-phase Cyril-radical for coexistent Cat-H₂ and a back-etch process competitive with deposition of SiN which is a mother layer is superimposed on the deposition of SiN.

This means only occurrence of the surface process inhibition of SiN being deposited and it is estimated that the occurrence is one factor of step coverage improvement through the shift of a system to the surface process rate-controlling side.

By using halogen-element-contained Si source gas such as SiH₂Cl₂ (dichlorosilane; DCS), Si₂Cl₆ (hexachlorodisilane; HCD), SiCl₄ (silicon tetrachloride; TCS), SiH₂F₂ (difluorosilane; DFS), or SiF₄ (silicon tetrafluoride; TFS), it is generally considered that good coverage cannot be easily obtained unless halogen-element-contained gas such as HCl or HF gas is separately added in the case of a thermal CVD system which uses saturated hydrogenated Si such as SiH₄ or SiH₆ as Si source gas differently from a thermal CVD system for involving oxidizing back-etch species during deposition.

It can be said that an Si-rich SiN film Cat-CVD system using [SiH₄/NH₃/H₂] material which extremely restrains supply of NH₃ is a rare and valuable CVD system in which H₂ can function as “reducing back etch species”.

This seems to be closely linked with the basic principle of Cat-CVD that the occurrence place of a radical related to deposition is made to be localized on a catalyst body far from a substrate.

Though a super high temperature close to 2000° C. ideal for occurrence of a Cat-H₂ radical can be used, it is estimated that formation of high-concentration stable H surfactant on the surface of a substrate being deposited will be prompted because it is possible to set the temperature of a substrate which is an adsorption medium of a generated Cat-H₂ radical to an ultra-low temperature optimum for and independently of the surface step control of film deposition and it is possible to change the gaseous phase between “a catalyst body and a substrate which is a transport medium to the substrate of the Cat-H₂ radical to a calm (and ultra-low-pressure having less deactivating opportunity) gaseous phase)” in which discharge is not present.

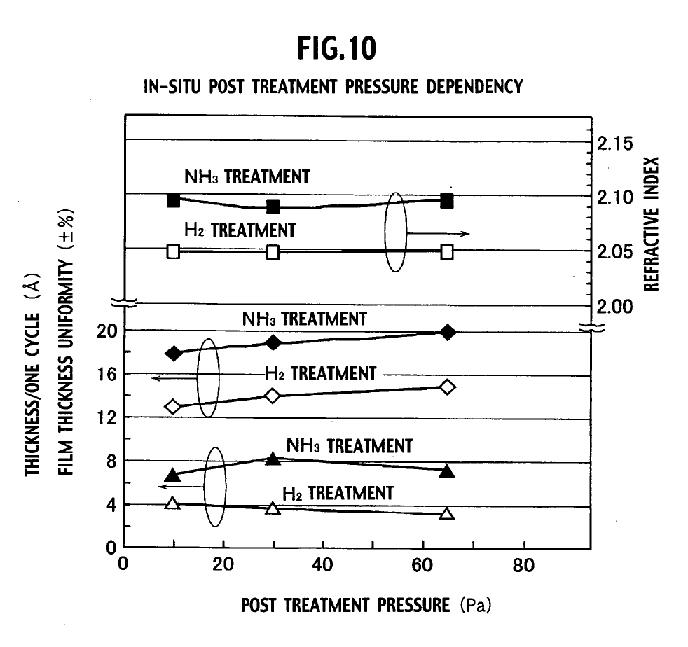

FIG. 10 is an illustration showing the refractive index of 100 nm-thick SiN obtained by laminating approx. 100 1 nm-thick SiN unit layers, film forming speed for unit layer, and in-situ post-processing-pressure dependency of a film thickness distribution in the face of an 8-inch substrate.

FIG. 10 shows that the refractive index, film forming speed, and in-face film-thickness uniformity hardly depend on processing pressure but they are influenced by the post-processing atmosphere (gas species), that is, difference between ammonia gas and hydrogen gas.

In this case, the post processing atmosphere is an atmosphere corresponding to “atmosphere A” among continuous post-processing procedures shown as, for example, A(20 sec)→exhaust (5 sec)→NH₃ (10 sec). That is, NH₃ treatment is performed by all means independently of gas species selection in “atmosphere A”.

By setting “atmosphere A” to NH₃, the refractive index, film forming speed for unit layer, and 8-inch-substrate in-face film-thickness distribution are significantly lowered when applying the post processing having complex content to a period to be Cat-H₂-applied by using “atmosphere A” as H₂ compared to the case of applying the in-situ post processing constituted of only Cat-NH₃ irradiation by using “atmosphere A” as NH₃.

In the case of the leak current measured by an MIS-structural capacitor using these SiN films as dielectric materials, the period of Cat-CVD SiN to be Cat-H₂-applied laminated by applying set compound post processing is smaller than that of post processing only Cat-NH₃-irradiated.

The possibility of Cat-H₂ serving as a surface-process inhibitory surfactant in Si-rich SiNCat-CVD system is described. However, hydrogenated back etching to the vapor-phase Cyril-radical of surplus Si on the surface during deposition in this case suggests the possibility of Cat-H₂ serving as an SiN-composition corrigent during the post-processing period in the meaning of “extraction of surplus Si”.

It seems that the above result shows that not only “post nitrification” for compensating insufficient N but also “Si extraction” for removing surplus Si are effective as composition correcting means of an Si-rich SiN film.

FIG. 12 is an illustration showing the influence of irradiation sequence of gas atmosphere at the time of “compound post processing” using Cat-H₂ irradiation and Cat-NH₃ irradiation together on leak current.

As shown in FIG. 12, in the case of the post processing constituted of only Cat-H₂ irradiation (without relating to Cat-NH₃ irradiation), it is shown that, rather than little effect of the sequence, the composition correcting effect is insufficient.

Therefore, “Si extraction” and “post nitrification” should be used in combination for stoichiometric composing.

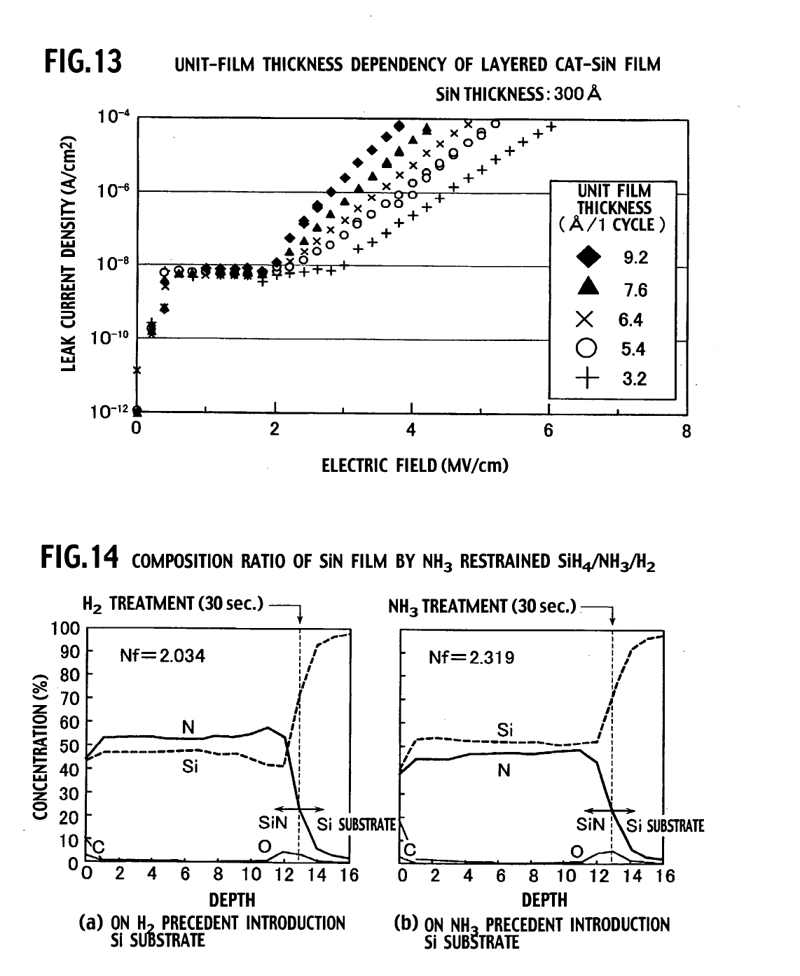

FIG. 13 is an illustration showing the unit-layer film thickness dependency of the leak current of a laminated SiN film by Cat-CVD for each unit layer for applying “compound post processing” in which a processing condition is optimized.

As shown in FIG. 13, the lead current decreases as the unit-layer film thickness decreases. Therefore, the leak current is decreased and electrical characteristic is improved as decreasing the deposited film thickness per cycle, preferably performing post processing every unit layer by using a single molecular layer as a unit.

Then, the sequence of gas introduction in this embodiment is described below.

It is widely known that the introduction sequence of source gases at start of CVD conclusively influences the characteristic of the “substrate<=>deposited film” through the influence on the initial nucleus occurrence process on the surface of a substrate.

FIGS. 14(a) and 14(b) are illustrations showing the surface treatment due to difference between gas species and film-thickness-directional element profiles of SiN films.

Examples shown in FIGS. 14(a) and 14(b) respectively show a step of initially introducing only NH₃ or H₂ for 30 sec immediately before start of film formation when forming a single-layer SiN film having a thickness of 30 nm through Cat-CVD of [SiH₄/NH₃/H₂] material is set. Each flow rate at the time of film formation is [SiH₄/NH₃/H₂]=[7/10/10] sccm, which is a condition for obtaining extremely Si-rich but good step coverage. NH₃ or H₂ flow rate at the time of precedent introduction for 30 sec is the same as that at the time of film formation.

At the time of precedent introduction of NH₃, SIN-CVD is started by introducing SiH₄ and H₂ at the same time when 30 sec passes after introduction but at the time of precedent introduction of H₂, SiN-CVD is started by introducing SiH₄ and NH₃ at the same time.

Cat-CVD of single-layer SiN uses “precedent introduction of NH₃ for 30 sec” as standard.

As shown in FIGS. 14(a) and 14(b), though the gas condition at the time of film formation is the same, the film composition is greatly different not only in the vicinity of the [Si substrate<=>deposited film] but also over the whole film-thickness direction depending on the kind of gas to be precedently introduced.

Moreover, in the case of the Cat-CVD of “H₂ precedent introduction”, NH₃ supply at the time of film formation is extremely restrained. However, SiN having insufficient step coverage similar to the time of Cat-CVD to which NH₃ is sufficiently supplied is deposited, great reduction of the refractive index and remarkable increase of the deposition rate (approx. 2 times for this example) are observed. Therefore, it seems that the resolution efficiency of NH₃ is improved.

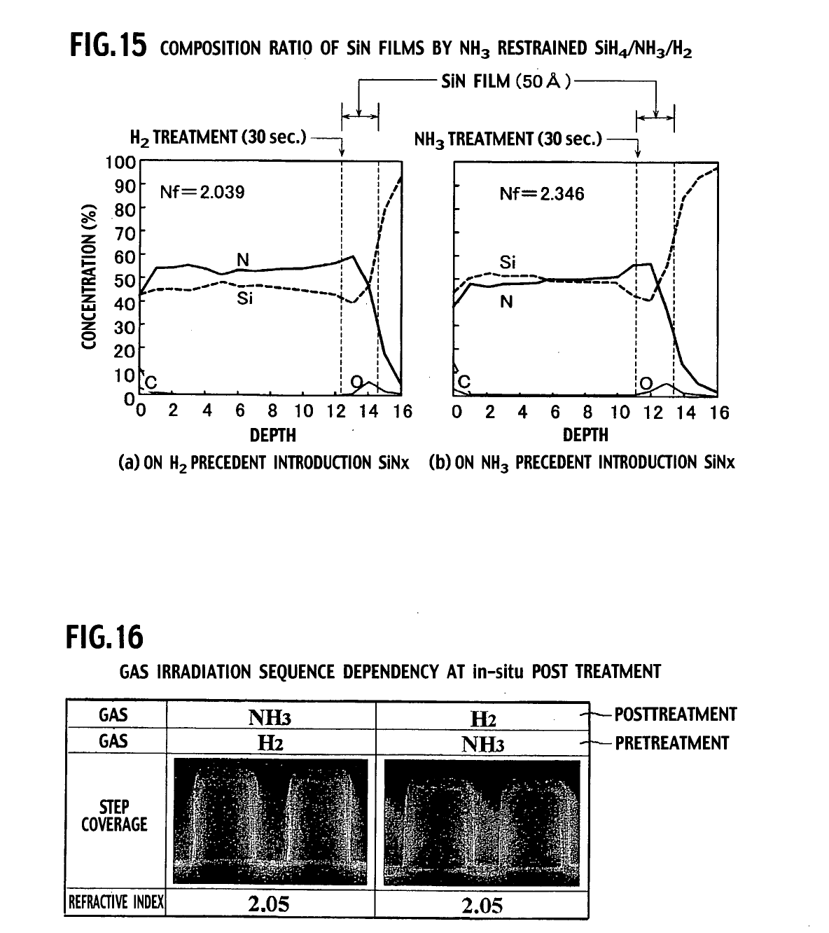

FIGS. 15 (a) and 15(b) respectively show a case of using an Si substrate on which an SiN film having a thickness of 5 nm is previously formed on the surface of a substrate. This is the same trend as a case of directly forming a film on an Si substrate without depending on the composition of the underlaid SiN.

Therefore, the property of the whole deposited film is decided insensitively for the decorative state or material of the surface of the substrate. It is suggested that the root of the above phenomenon lies not in the step on the substrate surface but in the step on the Cat line surface when considering a state peculiar to Cat-CVD that there is a Cat-line surface which is a radical generation place in addition to the substrate surface which is the adsorption medium of a generated radical as the “surface” relating to a system.

In the case of Cat-CVD, to deposit SiN having a stoichiometric composition, it has been necessary so far to realize an abnormally-large [NH₃/SiH₄] supply ratio (normally, 20 or more) compared to, for example, a plasma CVD system. This has been attributed to unavoidable decrease of NH₃ decomposition efficiency when SiN₄ and NH₃ are coexistent on a Cat line.

However, great improvement of the decomposition efficiency of NH₃ when precedently introducing H₂ suggests that the catalyst performance of a Cat line deteriorated due to self poisoning at the time of the polygenetic gas system using step can be reproduced by H₂ exposure immediately before.

From this point of view, in a layer-by-layer CVD system which is a circulative film-forming step, attention must be paid to a point that the post treatment immediately after a certain unit-layer film formation also has the pretreatment function of the next unit-layer film formation.

Therefore, it is preferable that continuous post treatment due to introduction of Cat-H₂ and Cat-HN₃ is ended by Cat-NH₃ introduction in order to obtain high step coverage.

FIG. 16 is an illustration showing gas-introduction sequence dependency at the time of post processing.

As shown in FIG. 16, in the case of the influence of irradiation sequence of Cat-H₂ and Cat-NH₃ during “in-situ post treatment” on step coverage of laminated SiN, step coverage is completely changed even with the same refractive index. Therefore, to obtain high step coverage, it is very effective to introduce ammonia as post treatment after forming a unit film.

Then, the film quality by this embodiment is described below.

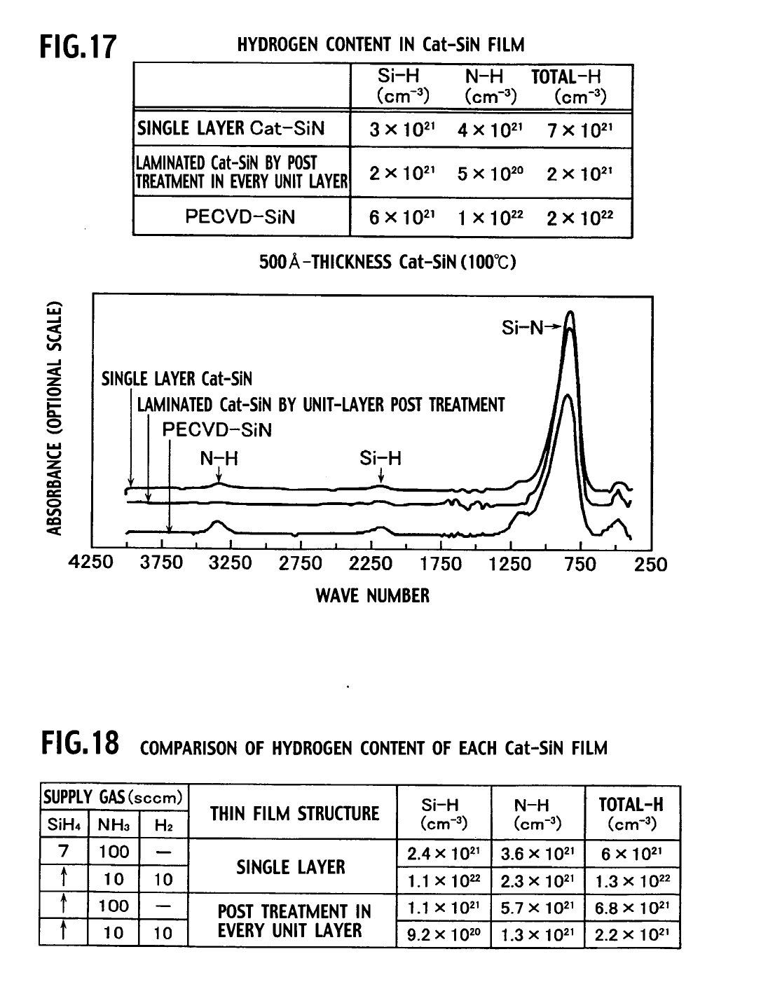

FIG. 17 is an illustration showing hydrogen contents of a single-layer film of standard Cat-SiN, laminated-layer film by adaptive Cat-SiN-unit-layer unit post treatment and single-layer film of PECVD-SiN.

As a result of evaluating the hydrogen content of an SiN film through FTIR spectrum, the hydrogen content of the film is decreased in the case of the layer-by-layer CVD step of this embodiment as shown in FIG. 17.

It is known since before that the contained hydrogen quantity is smaller than the case of that by PECVD also in the case of a single-layer Cat-CVD SiN film of a conventional standard condition for sufficiently supplying NH₃. However, when forming a film through “in-situ compound post treatment” Cat-CVD using Cat-H₂ irradiation and Cat-NH₃ irradiation together every unit layer like the case of this embodiment, the contained hydrogen quantity is further decreased up to approx. 2.2×10²¹ cm⁻³.

FIG. 18 is an illustration comparing influences of H₂ addition, HN₃ supply restraint, and laminated film structure on contained hydrogen quantity.

From FIG. 18, in the case of Cat-CVD of an [SiH₄/NH₃/H₂] material to which H₂ is added and in which HN₃ supply is extremely restrained, the hydrogen content of a laminated SiN film using an Si-rich SiN film as a unit layer is rather smaller than that of a Cat-CVD SiN using the [SIH₄/NH₃] material to which H₂ is not added but HN₃ is sufficiently supplied independently of laminated film or single-layer film.

Moreover, when H₂ is not added to source gas, the contained-hydrogen reduction effect is not realized even by change to a laminated film.

Furthermore, the hydrogen content is maximized in the case of a single-layer thick film even if an Si-rich SiN film is used in the case of Cat-CVD of an [SiH₄/NH₃/H₂] material to which H₂ is added but supply of NH₃ is extremely restrained.

As described above, a surface treating step by hydrogen gas is extraction of surplus Si and surface treatment by ammonia gas is additional treatment for compensating N. However, it is possible to improve the uniformity of a film thickness and film quality by a step obtained by complexing the above treatment.

Moreover, by surface-treating the final step of one cycle by ammonia gas, step coverage is greatly improved.

Thus, in the case of the unit-layer post-treatment film forming method of this embodiment, it is possible to form a thin film having preferable in-face film thickness uniformity, step coverage, and film quality.

### EXAMPLES

Then, examples are described.

### Example 1

As shown in FIG. 1, in the case of Example 1, a heater 7 is electrified and resistance-heated under a reduced pressure of 10 Pa, a substrate 5 on a substrate holder 6 is heated up to, for example, 200° C., a catalyst body (such as tungsten thin wire) 8 is electrified and resistance-heated up to 1,700° C.

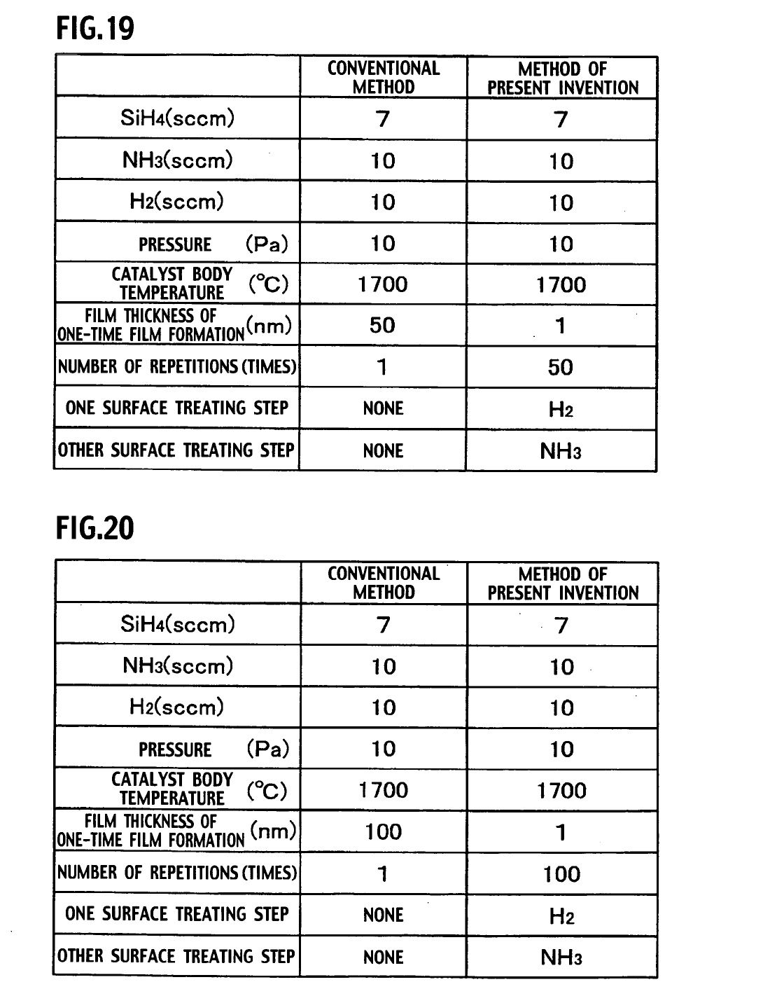

As film forming conditions, the flow rate of silane gas (SiH₄) is 7 sccm, flow rate of ammonia gas (NH₃) is 10 sccm, flow rate of hydrogen gas (H₂) is 10 sccm, pressure in the reactive vessel 2 is 10 Pa, and temperature of the catalyst body 8 is 1,700° C. as shown in FIG. 19. In the case of this example, a very-thin silicon nitride film having a thickness of 1 nm is obtained.

In the timing chart shown in FIG. 2, a silicon nitride film having the total thickness of 50 nm is finally obtained by using a film forming step and one and other surface treating steps as one cycle and continuously repeating the film forming step of one cycle and one and other surface treating steps 50 times in the case of this embodiment.

The hydrogen concentration (hydrogen content) in a silicon nitride film measured by a Fourier-transform infrared spectrophotometer (FTIR) for a silicon nitride film having the total thickness of 50 nm is 2×10²¹ atom/cm³.

However, the hydrogen concentration in the silicon nitride film having a thickness of 50 nm formed through one-time film forming step like the case of a conventional method measured by a Fourier-transform infrared spectrophotometer (FTIR) is 7×10²¹ atom/cm³.

In the case of the conventional film forming conditions in this case, as shown in FIG. 19, the flow rate of silane gas (SH₄) is 7 sccm, flow rate of ammonia gas (NH₃) is 10 sccm, flow rate of hydrogen gas (H₂) is 10 sccm, pressure in the reactive vessel 2 is 10 Pa, and temperature of the catalyst body 8 is 1,700° C. (these conditions are the same as the case of the film forming method of an embodiment of the present invention) and a silicon nitride film having a thickness of 50 nm is obtained through one-time film forming step in this case.

As clarified from this result, according to a film forming method of the present invention for finally obtaining a silicon nitride film having a desired thickness by using a film forming step of the present invention and one and other surface treating steps as one cycle and continuously repeating the film forming step of one cycle and one and other surface treating steps a plurality of times, the hydrogen concentration is greatly decreased from the hydrogen concentration of a silicon nitride film obtained through a conventional film forming method.

Therefore, it is possible to provide a high-reliability high-quality silicon nitride film for a long time without the fact that the leak current when a high electric field is applied is not increased.

### Example 2

In the case of the Example 1, a silicon nitride film having a thickness of 50 nm is finally formed by forming a silicon nitride film having a thickness of 1 nm in one film forming step and continuously repeating one-cycle step of the film forming step and one and other surface treating steps 50 times. In the case of the Example 2, however, a silicon nitride film having a thickness of 1 nm is formed in a step of one cycle by the film forming method same as the case of the Example 1 and a silicon nitride film having a thickness of 100 nm is finally formed by continuously repeating the surface treatment step of one cycle 100 times.

In the case of step film forming conditions in this time, as shown in FIG. 20, the flow rate of silane gas (SiH₄) is 7 sccm, flow rate of ammonia gas (NH₃) is 10 sccm, flow rate of hydrogen gas (H₂) is 10 sccm, pressure in the reactive vessel 2 is 10 Pa, and temperature of the catalyst body 8 is 1,700° C. (these conditions are the same as the case of the Example 1) and a silicon nitride film having a thickness of 1 nm is obtained through one-time film forming step in this case.

Moreover, hydrogen gas is introduced in one surface treating step similarly to the case of the embodiment 1 also in the Example 2 and ammonia gas is introduced in other surface treating step.

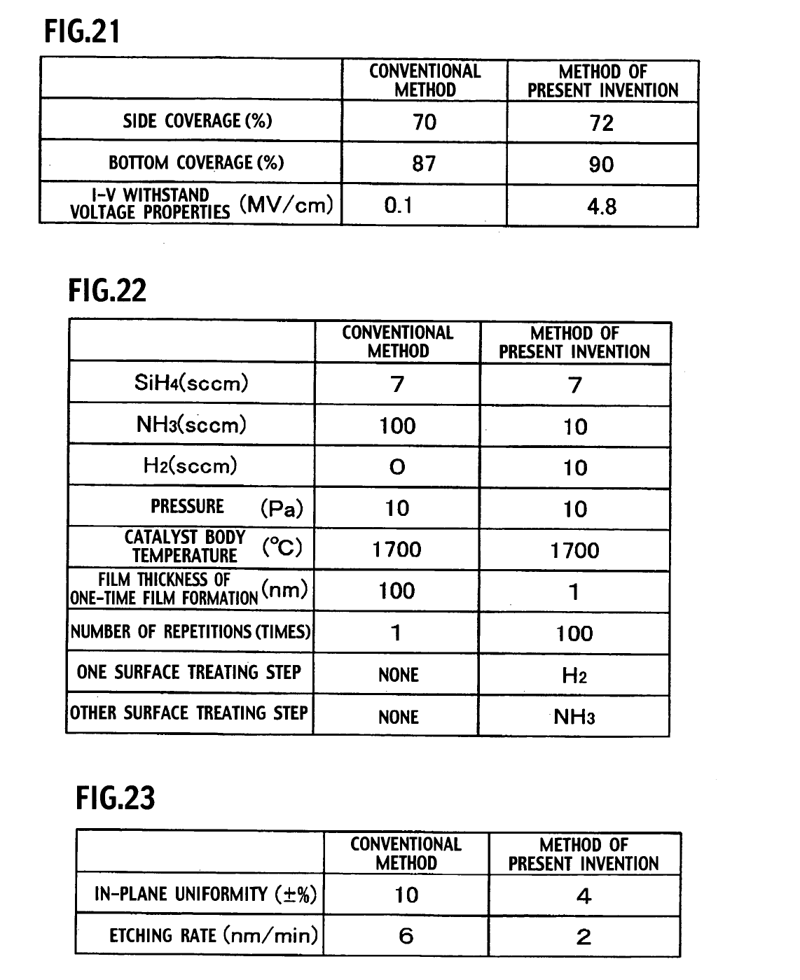

As a result of measuring the step coverage (%) and current-voltage (I-V) electric withstand voltage characteristic (MV/cm) of a silicon nitride film having the total thickness of 100 nm obtained through the film forming method by the Example 2, measurement results shown in FIG. 21, that is, results that the side coverage of a silicon nitride film is 72%, bottom coverage of it is 90%, and I-V electric characteristic withstand voltage is 4.8 MV/cm are obtained.

Moreover, as a result of measuring the coverage (%) and current-voltage (I-V) electric characteristic withstand voltage (MV/cm) for a silicon nitride film having a thickness of 100 nm formed through one-time film forming step like the case of a conventional method for comparison for the film forming method of the Example 2, measurement results shown in FIG. 21, that is, results that side coverage of a silicon nitride film is 72%, bottom coverage of it is 90%, and I-V electric characteristic withstand voltage is 0.1 MV/cm or lower are obtained.

In the case of film forming conditions in this case, as shown in FIG. 20, the flow rate of silane gas (SiH₄) is 7 sccm, flow rate of ammonia gas (NH₃) is 10 sccm, flow rate of hydrogen gas (H₂) is 10 sccm, pressure in the reactive vessel 2 is 10 Pa, and temperature of the catalyst body 8 is 1,700° C. (these conditions are the same as the case of the film forming method of the Example 2) and a silicon nitride film having a thickness of 100 nm is obtained through one-time film forming step in this case.

As clarified from this result, by using a film forming method of the present invention for finally obtaining a silicon nitride film having a desired thickness by assuming the above-described film forming step, one and other surface treating steps as one cycle and continuously repeating the film forming step of one cycle, a surface treating step, and other surface treating step a plurality of times, step coverage and I-V electric withstand voltage characteristic are improved for a silicon nitride film obtained through a conventional film forming method.

### Example 3

In the case of Example 3, a silicon nitride film having a thickness of 1 nm is formed through one-time film forming step by the film forming method same as the case of the Example 2 and a silicon nitride film having a thickness of 100 nm is finally formed by continuously repeating the film forming step, one surface treating step, and other surface treating step 100 times.

In the case of film forming conditions in this case, as shown in FIG. 22, the flow rate of silane gas (H₂) is 7 sccm, flow rate of ammonia gas (HN₃) is 10 sccm, flow rate of hydrogen gas (H₂) is 10 sccm, pressure of the reactive vessel 2 is 10 Pa, and temperature of the catalyst body 8 is 1,700° C. (these conditions are the same as the case of the film forming method of the embodiment 2) and a very-thin silicon nitride film having a thickness of 1 nm is obtained in one-time film forming step for 10 sec in this case in the case of the Example 3.

Then, as a result of measuring the in-face uniformity of the thickness and the etching speed by buffered hydrofluoric acid of the formed silicon nitride film having a thickness of 100 nm, measurement results shown in FIG. 23, that is, results that the in-face uniformity is ±4% and the etching rate is 2 nm/min are obtained.

Moreover, as a result of measuring the in-face uniformity of the film thickness and etching rate by buffered hydrofluoric acid of a silicon nitride film having a thickness of 100 nm formed in one-time film forming step like the case of a conventional method for comparison for the film forming method of the Example 3, measurement results shown in FIG. 6, that is, results that the in-face uniformity is ±10% and etching rate is 6 nm/min are obtained.

In the case of the film forming conditions in this case, as shown in FIG. 22, the flow rate of silane gas (SiH₄) is 7 sccm, flow rate of ammonia gas (NH₃) is 100 sccm, flow rate of hydrogen gas (H₂) is 0 sccm, pressure in the reactive vessel 2 is 10 Pa, and temperature of the catalyst body 8 is 1,700° C. and a silicon nitride film having a thickness of 100 nm is obtained through one-time film forming step in this case.

As clarified from the result, by using a film forming method of the present invention for finally obtaining a silicon nitride film having a desired thickness by using a film forming step, one surface treating step, and other surface treating step as one cycle and continuously repeating the step of one cycle a plurality of times, it is possible to improve the in-face uniformity of the film thickness of a silicon nitride film obtained by a conventional film forming method and the corrosion resistance for an etching solution.

In the case of the above silicon-nitride-film forming method of the present invention, it is possible to optionally set the treating times of the film forming step, one surface treating step, and other surface treating step in one cycle and repetition times of the one cycle when continuously repeating the film forming step, one surface treating step, and other surface treating of one cycle step a plurality of times.

Moreover, it is allowed to optionally adjust the pressure in the reactive vessel 2 when changing the film forming step, one surface treating step, and other surface treating step in this one cycle.

Furthermore, it is allowed to alternately repeat one surface treating step and other surface treating step after the film forming step in this one cycle a plurality of times.

### INDUSTRIAL APPLICABILITY

A unit-layer post-treatment catalyst chemical-vapor deposition apparatus and unit-layer post-treatment film forming method of the present invention can form a laminated film using a single molecular layer as a unit and they are effective to form a thin film having preferable film-thickness in-face uniformity, step coverage, and film quality.

1. A unit-layer post-treatment catalyst chemical-vapor-deposition apparatus for forming a thin film on a substrate by using the catalyst action of an exothermic catalyst body resistance-heated in a reactive vessel capable of performing vacuum pumping, comprising:
a gas supply system capable of introducing flow rates of thin-film-component-contained gas and hydrogen gas into the reactive vessel like a pulse; and
an exhaust system capable of performing vacuum pumping and pressure control, wherein
the above thin-film-component-contained gas and hydrogen gas introduced like a pulse contact with the exothermic catalyst body and decompose and form a thin film for each unit layer on the substrate, and form a laminated thin film by surface-treating the thin film for each unit layer.

2. The unit-layer post-treatment catalyst chemical-vapor-deposition apparatus according to claim 1, characterized in that
the surface treatment is one or both of the surface treatment by thin-film-component-contained gas excluding silicon and containing active species and the surface treatment by hydrogen gas containing active species.

3. The unit-layer post-treatment catalyst chemical-vapor-deposition apparatus according to claim 1, characterized in that
the catalyst performance is regenerated by applying hydrogen gas to the exothermic catalyst body.

4. The unit-layer post-treatment catalyst chemical-vapor-deposition apparatus according to claim 1, characterized in that
the surface treatment is one or both of the extracting treatment of surplus thin-film component and direct adding treatment of a thin-film component.

5. The unit-layer post-treatment catalyst chemical-vapor-deposition apparatus according to claim 1, characterized in that
one of nitrogen gas and rare gas is used instead of the hydrogen gas.

6. The unit-layer post-treatment catalyst chemical-vapor-deposition apparatus according to claim 1, characterized in that
the thin-film-component-contained gas is made of at least one of hydride of silicon and halide of silicon, and at least one of nitrogen and hydride of nitrogen.

7. The unit-layer post-treatment catalyst chemical-vapor-deposition apparatus according to claim 1, characterized in that
the thin-film-component-contained gas containing active species in the surface treatment is one or both of nitrogen and hydride of nitrogen.

8. A unit-layer post-treatment film forming method which is a catalyst chemical-vapor-deposition method for forming a thin film on a substrate by using the catalyst action of an exothermic catalyst body resistance-heated in a reactive vessel capable of performing vacuum pumping, comprising:
an activating step of introducing flow rates of thin-film-component-contained gas and hydrogen gas like a pulse, bringing the gases into contact with the exothermic catalyst body, and generating active species;
a film forming step of forming a thin film for each unit layer on a substrate; and
a surface treating step of performing surface treatment of a thin film for unit layer by hydrogen gas containing active species, and another surface treating step of surface-treating a thin film every unit layer by thin-film-component-contained gas including active species, wherein the surface treating step and the other surface treating step can be carried out in any order; characterized in that
a laminated thin film is formed by using a series of steps for respectively performing surface treatment after forming a film as one cycle, and repeating a plurality of cycles.

9. The unit-layer post-treatment film forming method according to claim 8, characterized by repeating one of the one surface treating step and other surface treating step a plurality of times during one cycle.

10. The unit-layer post-treatment film forming method according to claim 8, characterized in that
one or both of the one surface treating step and other surface treating step and a film forming step of forming a thin film for each unit layer on a substrate are continuously performed.

11. The unit-layer post-treatment film forming method according to claim 8, characterized by vacuum-pumping remaining gas after one of the film forming step, the one surface treating step and other surface treating step.

12. The unit-layer post-treatment film forming method according to claim 8, characterized in that
the one surface treating step is a step of extracting a surplus thin-film component and the other surface treating step is a step of adding a thin-film component.

13. The unit-layer post-treatment film forming method according to claim 8, characterized in that
the final step of one cycle is a step of performing surface treatment by thin-film-component-contained gas excluding silicon and containing active species.

14. The unit-layer post-treatment film forming method according to claim 8, characterized in that
one of nitrogen gas and rare gas is used instead of the hydrogen gas.

15. The unit-layer post-treatment film forming method according to claim 8, characterized in that
the thin-film-component-contained gas is made of at least one of hydride of silicon and halide of silicon, and at least one of nitrogen and hydride of nitrogen.

16. The unit-layer post-treatment film forming method according to claim 8, characterized in that
the thin-film-component-contained gas including active species in the surface treatment is one or both of nitrogen and hydride of nitrogen.

17. The unit-layer post-treatment film forming method according to claim 8, characterized in that
the thin-film-component-contained gas is made of monosilane gas and ammonia gas, the film forming step forms a silicon nitride film for each unit layer on a substrate, and the other surface treating step is a step of surface-treating a silicon nitride film for each unit layer by ammonia gas including active species.

18. The unit-layer post-treatment film forming method according to any one of claims 15 to 17, characterized in that
the final step of one cycle is a step of performing surface treatment by ammonia gas which is thin-film-component-contained gas including active species.
